(19) United States
(12) Patent Application Publication
(10) Pub. No.: US 2012/0090657 A1
(43) Pub. Date: Apr. 19, 2012

(54) REDUCED LOW SYMMETRY FERROELECTRIC THERMOELECTRIC SYSTEMS, METHODS AND MATERIALS

(76) Inventors: Soonil Lee, State College, PA (US); Clive Randall, State College, PA (US); Rudeger H.T. Wilke, State College, PA (US); Susan Trolier-Mckinstry, State College, PA (US)

(21) Appl. No.: 13/377,736

(22) PCT Filed: Jun. 15, 2010
(86) PCT No.: PCT/US10/38575

§ 371 Date: Dec. 30, 2011

Related U.S. Application Data
(60) Provisional application No. 61/187,184, filed on Jun. 15, 2009.

(51) Int. Cl. H01L 35/30; H01L 35/34; H01L 35/14

(52) U.S. Cl. 136/205; 136/238; 136/240; 136/201

(57) ABSTRACT

n-type and p-type thermoelectric materials having high figures of merit are herein disclosed. The n-type and p-type thermoelectric materials are used to generate and harvest energy in thermoelectric power generator and storage modules comprising at least one n-type thermoelectric element coupled to at least one p-type thermoelectric element.

### CROSS REFERENCE TO RELATED APPLICATIONS

This application claims priority from U.S. provisional application No. 61/187,184, entitled “TUNGSTEN BRONZE MATERIALS FOR THERMOELECTRIC DEVICES,” filed on Jun. 15, 2009, which is incorporated by reference in its entirety, for all purposes, herein.

### FIELD OF TECHNOLOGY

The present disclosure is directed to thermoelectric systems, methods and materials. More particularly, the present disclosure is directed to low symmetry ferroelectric thermoelectric oxides systems, methods and materials.

### BACKGROUND

Thermoelectric materials can be used to convert thermal energy to electrical energy by exposing one side of the thermoelectric material to high temperature. The thermal gradient produces a difference in electric potential and causes electricity to flow across the thermoelectric material. This phenomenon, known as the Seebeck effect, facilitates thermoelectric conversion without the use of rotating equipment or gas combustion. The thermoelectric conversion efficiency of a particular thermoelectric material or device is defined by the figure of merit (ZT), expressed as ZT=TS²σ/k, where S is Seebeck coefficient, T is temperature, σ is the electrical conductivity, and k is the thermal conductivity. The power factor (PF), expressed as PF=S²σ, is a function of carrier concentration and is optimized through doping to maximize the figure of merit (ZT) of the thermoelectric material.

p-type oxide thermoelectric materials such as Ca₃Co₄O₉ have been used for high temperature thermoelectric conversion. However, current thermoelectric materials including p-type CoOₓ-based layered oxides and n-type oxides have relatively low figures of merit (ZT), low powers factors (PF) and are incapable of efficiently converting or storing energy generated at temperatures greater than 300° C.

There is therefore a need in the art to develop improved p-type and n-type thermoelectric systems, methods and material for efficient high temperature energy conversion and harvesting.

### BRIEF DESCRIPTION OF THE DRAWINGS

Embodiments of the present application are described, by way of example only, with reference to the attached Figures, wherein:

FIG. 1 illustrates an exemplary thermoelectric conversion and storage system according to one embodiment;

FIG. 2 illustrates a flow chart of an exemplary bulk and thick film casting process for creating tungsten bronze Sᵣ₁₋ₓBaₓNb₂O_{y} (SBN) and layered perovskite Sr₂Nb₂O₇ (SN) n-type and Li₁₋ₓNbO₂ (LN) p-type thermoelectric elements according to one embodiment;

FIG. 3 illustrates the Seebeck coefficient (S) as a function temperature of an exemplary single crystal n-type Sr₁₋ₓBaₓNb₂O_{6-y} at various levels of reduction according to one embodiment;

FIG. 4 illustrates the power factor (PF) as a function temperature of an exemplary single crystal n-type Sr₁₋ₓBaₓNb₂O₃, at various levels of reduction according to one embodiment;

FIGS. 5A through 5B illustrate the power factor (PF) as a function dopant concentrations of an exemplary A- and B-site donor-doped SBN [(Sr₁₋ₓBaₓ)_{1-y}D_{y}(Nb_{1-y}D_{y})₂O₆ reduced at low oxygen partial pressure (pO₂) according to one embodiment;

FIG. 6 illustrate the power factor (PF) as a function temperature of an exemplary polycrystalline n-type W-doped Sr₂Nb₂O₇ at various dopant concentrations according to one embodiment;

FIG. 7 illustrates the power factor (PF) as a function temperature of an exemplary textured polycrystalline n-type Sr₁₋ₓBaₓNb₂O_{y} reduced at low oxygen partial pressure (pO₂) according to one embodiment;

FIGS. 8A through 8B illustrate the phase stability of an exemplary SBN compound as a function temperature and oxygen partial pressure (pO₂) of an exemplary SBN polycrystalline according to one embodiment;

FIG. 9 illustrates the power factor (PF) as a function temperature of an exemplary reduced LiNbO₃ (Li₁₋ₓNbO₂ phase) single crystal according to one embodiment; and

FIGS. 10A through 10B illustrate the thermoelectric efficiency of exemplary thermoelectric devices in terms of the figure of merit (ZT) as a function temperature according to one embodiment.

### DETAILED DESCRIPTION

It will be appreciated that for simplicity and clarity of illustration, where considered appropriate, reference numerals may be repeated among the figures to indicate corresponding or analogous elements. In addition, numerous specific details are set forth in order to provide a thorough understanding of the example embodiments described herein. However, it will be understood by those of ordinary skill in the art that the example embodiments described herein may be practiced without these specific details. In other instances, methods, procedures and components have not been described in detail so as not to obscure the embodiments described herein.

Ferroelectric and related materials belong to over 30 crystal structural families. Ferroelectric materials undergo structural phase transitions to form a low temperature ferroelectric phase having spontaneous polarization. Electronic conductivity prevents the application of high fields across the ferroelectric and, as a result, the polarization cannot be altered. However, the lattice structural changes perturb the transport characteristics and in a number of cases high thermopower characteristics are exhibited. Ferroelectrics with tungsten bronze structures and layered perovskites herein disclosed host ferroelectric displacive phase transitions, have octahedral frame works that are of low symmetry, and as illustrated in the examples disclosed herein have remarkable thermoelectric properties.

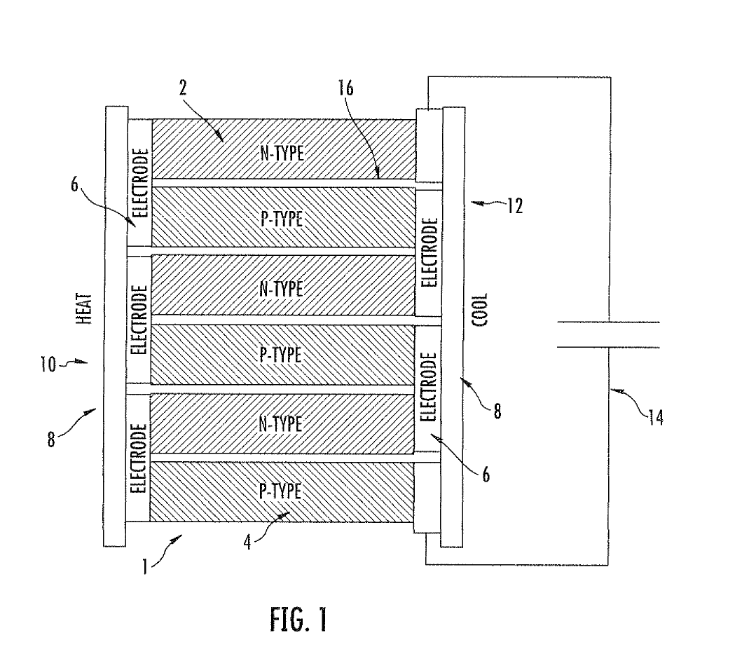

FIG. 1 illustrates an exemplary thermoelectric conversion and storage system 1 according to one embodiment. The exemplary thermoelectric conversion and storage system 1 can include one or more conductive n-type elements 2 coupled to one or more conductive p-type elements 4. One or more conductive n-type elements 2 and one or more conductive p-type elements 4 can be mechanically, thermally and/or electrically coupled to one another. A conductive n-type element 2 can be electrically coupled to a conductive p-type element 4 with one or more electrodes 6. A plurality of conductive n-type elements 2 and conductive p-type elements 4 can also be electrically coupled together with one or more electrodes 6. Insulator elements 14 can be positioned in between each n-type element 2 and p-type element 4 in the thermoelectric conversion and storage system 1. The thermoelectric conversion and storage system 1 can further include thermally conductive elements 8 coupled to one or more conductive n-type elements 2 and conductive p-type elements 4.

The thermally conductive elements 8 of the thermoelectric conversion and storage system 1 can be exposed to thermal energy (e.g., heat from any source) on a high temperature side 10 of the system 1. Exposing the high temperature side 10 to heat creates a thermal gradient in the axial direction from the high temperature side 10 to the low temperature side 12 of the system 1. The thermal gradient produces a difference in electric potential also in the axial direction that causes electricity or charge to flow from the high temperature side 10 to the low temperature side 12 of the system 1. The greater thermal gradient the greater the electricity generation across the thermoelectric conversion and storage system 1.

Electricity or charge generated from excess electrons within conductive n-type elements 2 can be flowed into holes of a conductive p-type elements 4. An electric circuit 14 or loop can be used to electrically connect at least one electrode 6 adjacent or proximate a conductive n-type element 2 to at least one electrode 6 adjacent or proximate a conductive p-type element 4 thus creating a current through the circuit 14. The electricity or charge generated from thermoelectric power generation can be stored through the circuit 14 within capacitors or batteries (not shown) electrically coupled to the thermoelectric conversion and storage system 1.

The conductive p-type elements 4 of the system 1 can comprise at least one compound selected from the group consisting of: Yb₁₄MnSb₁₁, NaCo₂O₄, Na_{1.5}Co_{1.8}Ag_{0.2}O₄, LaCoO₃, La_{0.98}Sr_{0.02}CoO₃, Si—Ge series materials, and Li₁₋ₓNbO₂ (LN) materials herein disclosed.

The conductive n-type elements 2 of the system 1 can comprise at least one compound selected from the group consisting of Bi₂Te₃, CaMn₁₋ₓRuₓO₃ wherein 0≦x≦1, Ca₁₋ₓSmₓMnO₃ wherein 0≦x≦1, Sr_{0.98}La_{0.02}TiO₃, Sr_{0.9}Dy_{0.1}TiO₃, SrTi_{0.8}Nb_{0.2}O₃, Zn_{0.98}Al_{0.02}O, Si—Ge series materials,

(Sr₁₋ₓDₓ)₂(Nb₁₋ₓDₓ)₂O₇ wherein D is any one of the following dopants: La, Y, Yb, Ta, Ti, V, W, U, or Mo donor dopants [SN, materials herein disclosed], and
(Sr₁₋ₓBaₓ)_{1-y}D_{y}(Nb_{1-y}D_{y})₂O₆ wherein 0≦x≦1 and 0≦y≦1 and wherein D is any one of the following dopants: La, Al, Ti, V, or W donor dopants and optionally others such as Me⁺³ (e.g. Y⁺³, Yb⁺³, etc.), and Me⁺⁶ (e.g. U⁺⁶ and Mo⁺⁶) [SBN materials herein disclosed].

The conductive p-type and n-type thermoelectric elements herein disclosed can be deposited on a semiconductor substrate with several deposition methods including but not limited to, physical vapor deposition (PVD), chemical vapor deposition (CVD), electrochemical deposition (ECD), molecular beam epitaxy (MBE) or atomic layer deposition (ALD). The thermoelectric conversion and storage systems herein disclosed can be bulk ceramic modules or thick film modules manufactured with the use of multilayer technology. The thermoelectric conversion and storage systems herein disclosed can also be thin film modules manufactured by sol-gel chemical deposition techniques.

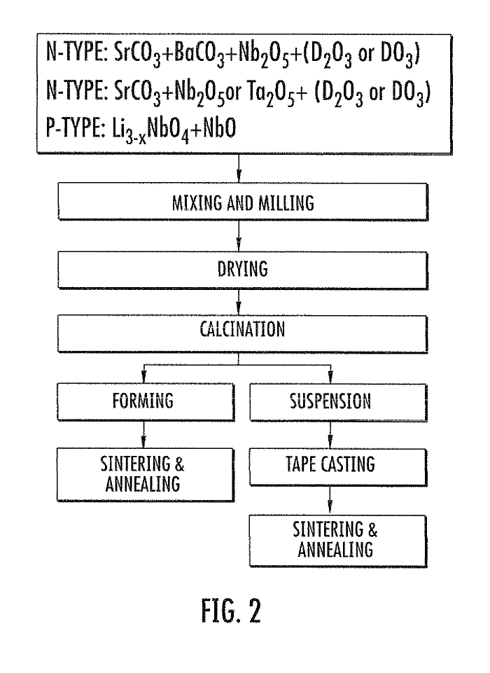

FIG. 2 illustrates a flow chart of an exemplary bulk or thick film casting process for creating tungsten bronze SBN and layered perovskite SN n-type and Li₁₋ₓNbO₂ p-type thermoelectric elements herein disclosed. Powder constituents including SrCO₃+BaCO₃+Nb₂O₅+(D₂O₃ or DO₃), where D can be La or W for instance (less than 50 mol %) are mixed or milled. The mixed and milled powder constituents are dried to remove moisture and heated by calcination to a temperature below their melting point to effect a thermal decomposition or a phase transition other than melting. The powder constituents can be mixed with a solvent to form a suspension. For thick film processes, the calcined powder is mixed together with a solvent to form a suspension. The solvent can be an organic solvent or water. Binders, plasticizers, dispersants and ceramic reinforcements can optionally be added to the suspension. The suspension can be tape-casted sintered and annealed to form n-type and p-type thin, bulk or thick films. The powder constituents can also be formed by hand or machine. The formed powder constituents can be sintered and annealed under designed conditions form n-type and p-type thin or thick films. Thin, bulk or thick films can be stacked by layer to form a thermoelectric module, as shown in FIG. 1.

The n-type and p-type materials herein disclosed can be manufactured through electronic oxide fabrication methods. The n-type and p-type materials herein disclosed can be in single crystal form or can be polycrystalline random and textured microstructures including thin film polycrystalline, textured, and epitaxial forms. The material dimensions of the thermoelectric elements and depositions herein disclosed depend on the desired thermoelectric module design and can include, but are not limited to single or multiple thin film layers between n- and p-type materials of about 1 nm to 50 microns or thick film cast layers of about 0.1 microns to 500 microns. The various techniques used to deposit n-type and p-type materials upon substrates to form thermoelectric modules herein disclosed include, but are not limited to colloidal techniques, chemical deposition techniques and physical vapor deposition techniques.

Table 1 provides a comparison of the Seebeck coefficient (S), resistivity (ρ), thermal conductivity (k), power factor (PF) and figure of merit (ZT) of exemplary oxide and non-oxide p-type thermoelectric materials. p-type Na_{C}o₂O₄ was found to have superior thermoelectric properties including low thermal conductivity, a high figure of merit (ZT) and a high power factor (PF) at high temperatures.

TABLE I
Electrical and Thermal Properties of p-Type Thermoelectric Materials

| | S | ρ | k | PF = S²/ρ | |
|---|---|---|---|---|---|
| p-type | (uV/K) | (Ωcm) | (W/mK) | (μW/cmK²) | ZT |
| Yb₁₄MnSb₁₁ | 185 | 0.0054 | 0.7 | 6 | 1 |
| 0.23B-0.77Si_{.08}Ge_{0.2} | 168 | 0.0012 | 4.1 | 23.1 | 0.62 |
| NaCo₂O₄ | 100 | 0.0002 | 2 | 50 | 0.75 |
| NaCo₂O₄ | 80 | 0.003 | 2 | 2 | 0.032 |
| Na_{1.5}Co_{1.8}Ag_{0.2} | 101 | 0.0066 | | 1.57 | |
| LaCoO₃ | 635 | 15.6 | | 0.0258 | |
| La_{0.98}Sr_{0.02}CoO₃ | 330 | 0.265 | | 0.411 | |

Table II provides a comparison of the Seebeck coefficient (S), resistivity (ρ), thermal conductivity (k), power factor and figure of merit (ZT) of exemplary oxide and non-oxide n-type thermoelectric materials in accordance with the present disclosure. Single crystal and polycrystalline n-type strontium barium niobate materials (SBN) having the formula Sr₁₋ₓBaₓNb₂O₆ were found to have superior thermoelectric properties including low thermal conductivity, a high figure of merit (ZT) and a high power factor (PF) at high temperatures.

TABLE II
Electrical and Thermal Properties of n-Type Thermoelectric Materials

| | | | | PF = S²/ρ | |
|---|---|---|---|---|---|
| | S | ρ | k | (μW/ | |
| n-type | (uV/K) | (Ωcm) | (W/mK) | cmK²) | ZT |
| Bi₂Te₃ | −200 | 0.001 | | 40 | 1.2 |
| 0.59P-0.41Si_{.08}Ge_{0.2} | −171 | 0.00074 | 4.2 | 39.3 | 1.15 |
| CaMn₁₋ₓRuₓO₃ | −140 | 0.005 | 4.0 | 4 | 0.030 |
| Ca₁₋ₓSmₓMnO₃ | −120 | 0.002 | 6.0 | 7 | 0.036 |
| Sr_{0.98}La_{0.02}TiO₃ | −260 | 0.001 | 11 | 67.6 | 0.18 |
| Sr_{0.9}La_{0.1}TiO₃ | −105 | 0.0033 | 5.82 | 3.3 | 0.017 |
| Sr_{0.9}Dy_{0.1}TiO₃ | −105 | 0.0016 | 3.39 | 6.8 | 0.06 |
| Thin Film | −200 | | 3.0 | 13.0 | 0.37 |
| SrTi_{0.8}Nb_{0.2}O₃ | | | | | |
| Single Crystal | −208 | 0.00106 | 0.95 | 40.8 | 2.36 |
| Reduced-Sr₁₋ₓBaₓNb₂O₆ | (550K) | | 2.28 | (550K) | 1.0 |
| Polycrystalline | −147 | 0.00307 | 0.95 | 7.0 | 0.41 |
| Reduced-Sr₁₋ₓBaₓNb₂O₆ | (550K) | | 2.28 | (550K) | 0.17 |

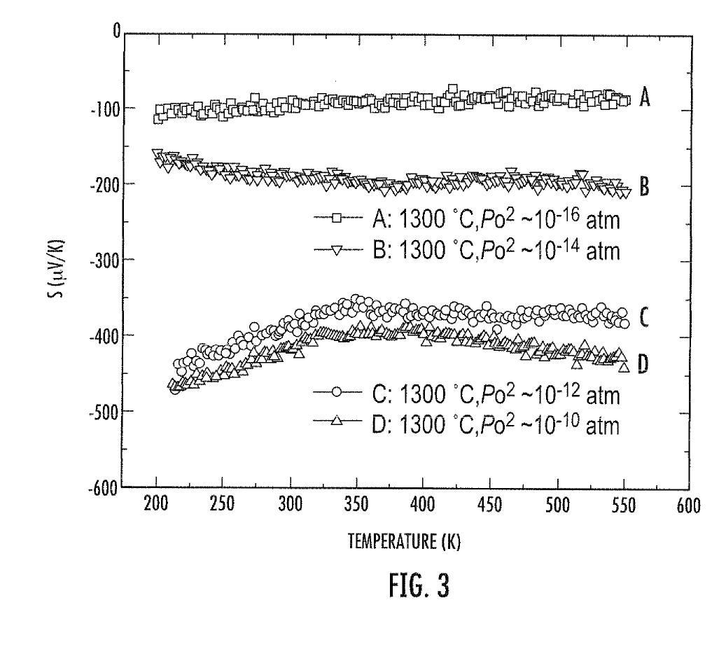

FIG. 3 illustrates the c-axis Seebeck coefficient (S) as a function temperature of an exemplary single crystal n-type Sr₁₋ₓBaₓNb₂O_{6-y} at various levels of reduction wherein 0≦x≦1. The crystals were annealed at 1300° C. under the following oxygen partial pressures (pO₂): Sample A: 10⁻¹⁶ atm O₂, Sample B: 10⁻¹⁴ atm O₂, Sample C: 10⁻¹² atm O₂ and Sample D 10⁻¹⁰ atm O₂. It was found that single crystal n-type Sr₁₋ₓBaₓNb₂O_{6-y} maintained a high Seebeck coefficient at high temperatures and after high levels of reduction.

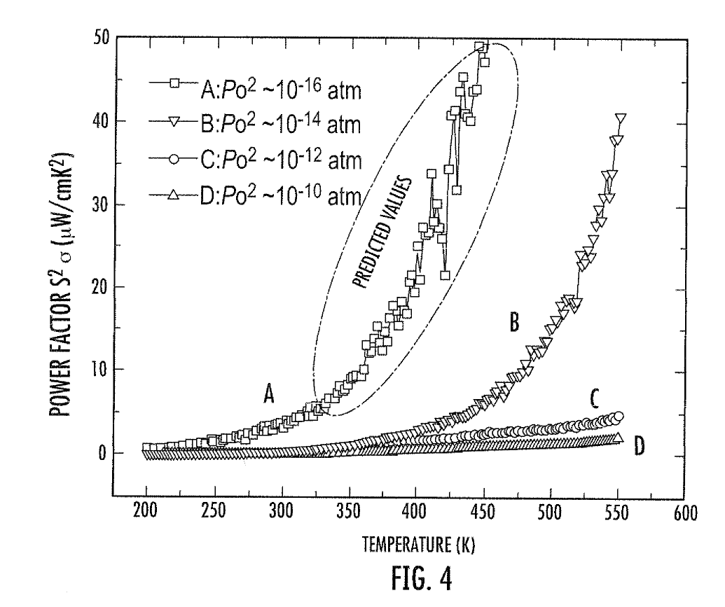

FIG. 4 illustrates the c-axis power factor (PF) as a function temperature of an exemplary single crystal n-type Sr₁₋ₓBaₓNb₂O_{6-y} at various levels of reduction wherein 0≦x≦1. The crystals were annealed at 1300° C. under the following oxygen partial pressures (pO₂): Sample A: 10⁻¹⁶ atm O₂, Sample B: 10⁻¹⁴ atm O₂, Sample C: 10⁻¹² atm O₂ and Sample D 10⁻¹⁰ atm O₂. It was found that single crystal n-type Sr₁₋ₓBaₓNb₂O_{6-y} maintained high power factors (PF) at high temperatures and after high levels of reduction.

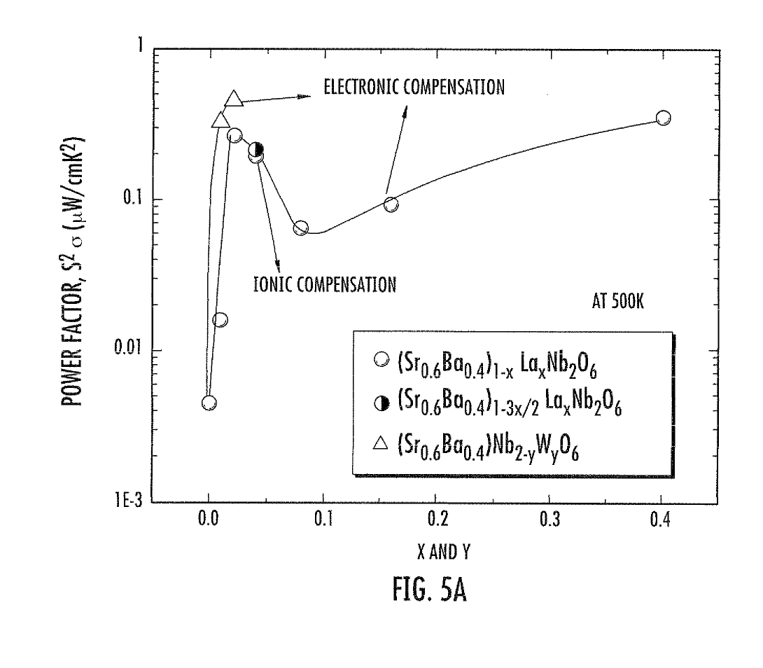

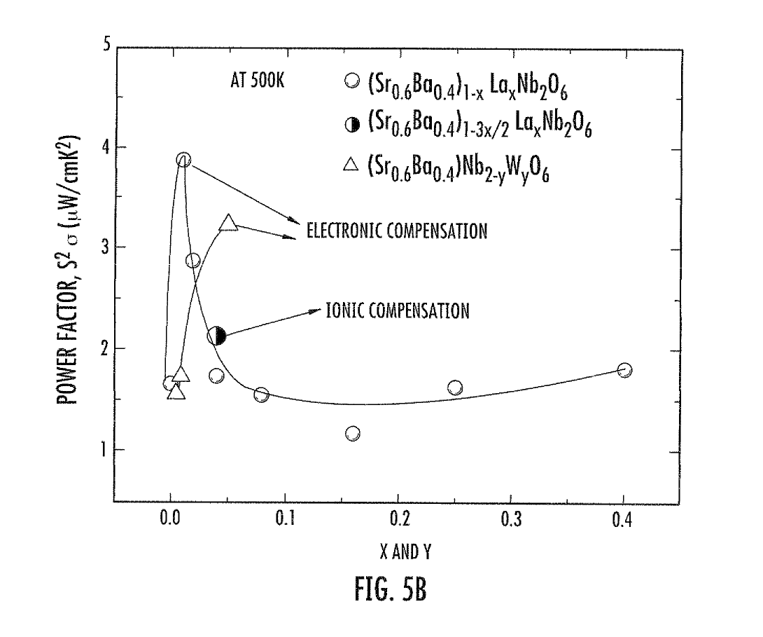

FIGS. 5A through 5B illustrate the power factor (PF) as a function dopant concentrations of an exemplary A- and B-site donor-doped SBN [(Sr₁₋ₓBaₓ)_{1-y}D_{y}(Nb_{1-y}D_{y})₂O₆ wherein D is La or W and reduced at 1300° C. under N₂ gas flow in one example illustrated in FIG. 5A and under a partial pressure of oxygen of pO₂˜10⁻¹⁴ atm in another example illustrated in FIG. 5B. It was found that the thermoelectric power factor was significantly improved by doping with La and W as compared with undoped SBN.

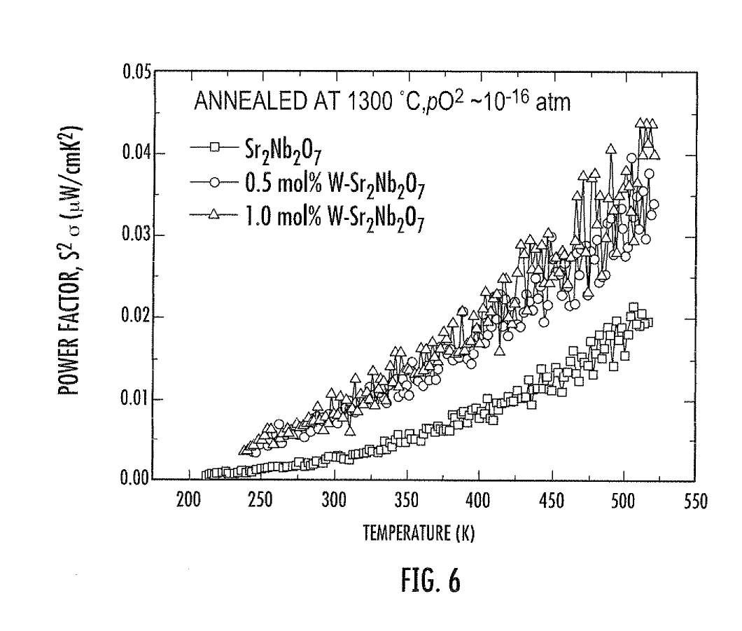

FIG. 6 illustrates the power factor (PF) as a function temperature of an exemplary polycrystalline n-type W-doped Sr₂Nb₂O₇ at various dopant concentrations according to one embodiment. The polycrystallines were sintered at 1500° C. and then annealed at 1300° C. under a partial pressure of oxygen of pO₂˜10⁻¹⁶ atm. It was found that there is a decoupling between the electrical conductivity and the thermopower, and electrical conductivity and the thermopower increase with increasing temperature. The power factor was improved by donor doping with W (tungsten) herein disclosed.

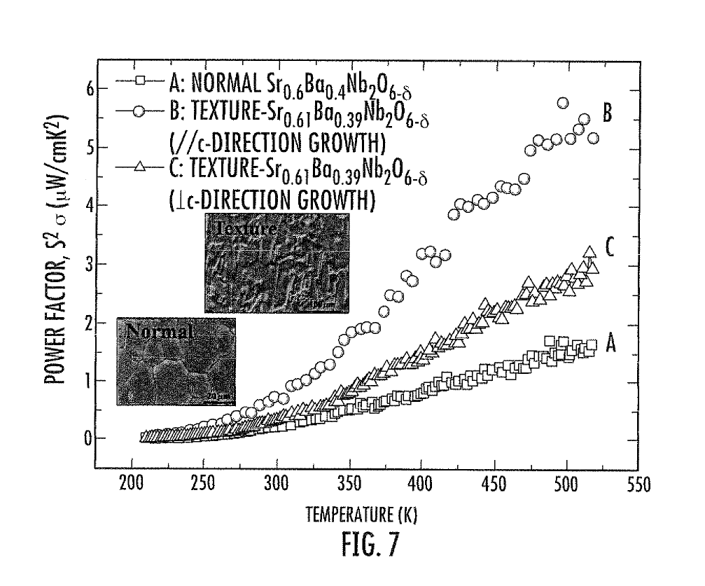

FIG. 7 illustrates the power factor (PF) as a function temperature of an exemplary textured polycrystalline n-type Sr₁₋ₓBaₓNb₂O_{6-y} wherein 0≦x≦1 according to one embodiment. The textured polycrystalline were annealed at 1300° C. under a partial pressure of oxygen of pO₂˜10⁻¹⁴ atm. It was found that the textured (parallel to c-axis) polycrystalline n-type Sr₁₋ₓBaₓNb₂O_{6-y} has significantly higher power factors (PF) than a normal polycrystalline n-type Sr₁₋ₓBaₓNb₂O_{6-y}.

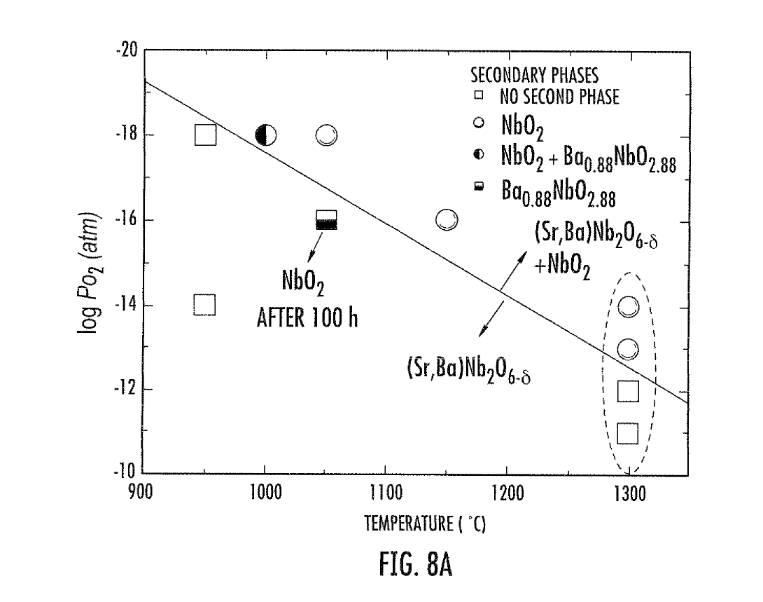

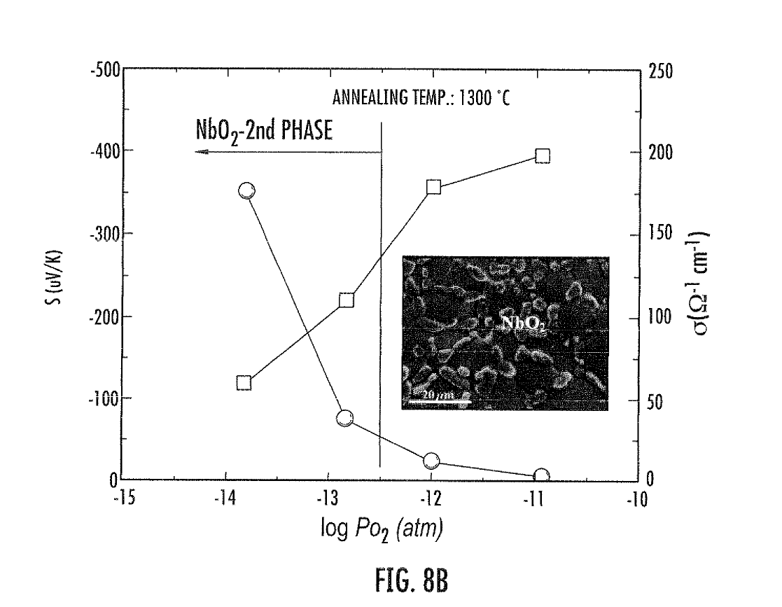

FIGS. 8A through 8B illustrate the phase stability of SBN compounds as a function temperature and oxygen partial pressure (pO₂) of an exemplary SBN polycrystalline. It was found that at low pO₂ conditions the high electrical conductivity and consequently high thermoelectric power factor (PF) resulted from the presences of a high nonstoichiometric matrix and a reduction secondary phases such as NbO₂.

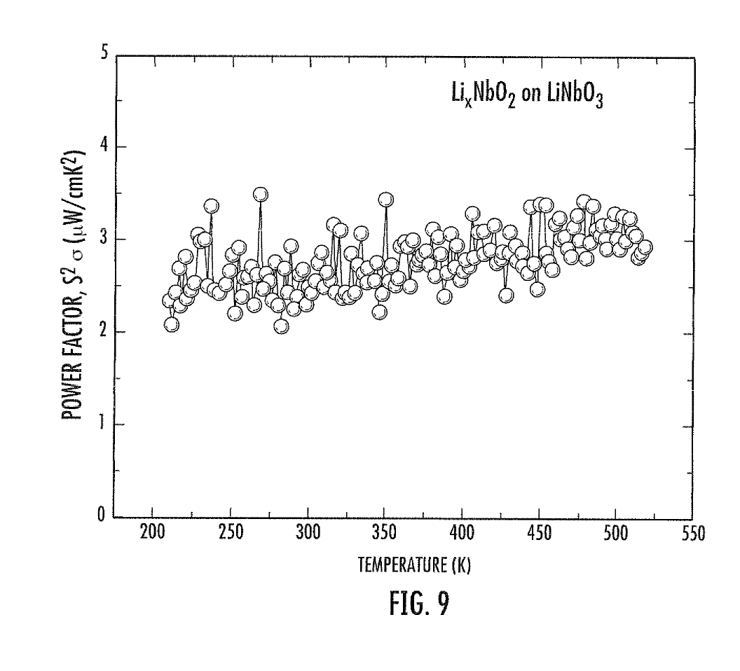

FIG. 9 illustrates the power factor (PF) as a function temperature of an exemplary reduced signal crystal LiNbO₃ (Li₁₋ₓNbO₂ phase) according to one embodiment. The Li₁₋ₓNbO₂ phase resulted from the annealing of LiNbO₃ at 1200° C. under a partial pressure of oxygen of pO₂˜10⁻¹⁸ atm. It was found that the power factor (PF) of Li₁₋ₓNbO₂ phase is comparable to that of NaₓCo₂O₄.

The p-type and n-type thermoelectric elements herein disclosed can be thermally and electrically coupled to form a thermoelectric power generator and storage module for generating and harvesting energy. The thermoelectric power generator and storage module includes at least one n-type thermoelectric element thermally and electrically coupled to at least one p-type thermoelectric element. A thermally conductive element can be used to thermally couple the n-type thermoelectric element to the p-type thermoelectric element. An electrically conductive element can be used to electrically couple the n-type thermoelectric element to the p-type thermoelectric element. The thermally conductive element and the electrically conductive element can comprise the same material or dissimilar materials. At least one conductive element can be used to thermally and electrically couple the n-type thermoelectric element to the p-type thermoelectric element. The n-type thermoelectric element may also be directly coupled to the p-type thermoelectric element to conduct heat and electricity across the thermoelectric power generator and storage module.

The p-type thermoelectric element may comprise at least one compound selected from the group consisting of: Yb₁₄MnSb₁₁, NaₓCo₂O₄, Na_{1.5}Co_{1.8}Ag_{0.2}O₄, LaCoO₃, La_{0.98}Sr_{0.02}CoO₃ and Si—Ge series material, and Li₁₋ₓNbO₂ (LN) materials.

The n-type thermoelectric element may comprise at least one compound selected from the group consisting of: Bi₂Te₃, CaMn₁₋ₓRuₓO₃ wherein 0≦x≦1, Ca₁₋ₓSmₓMnO₃ wherein 0≦x≦1, Sr_{0.98}La_{0.02}TiO₃, Sr_{0.9}Dy_{0.1}TiO₃, SrTi_{0.8}Nb_{0.2}O₃, Zn_{0.98}Al_{0.02}O, Si—Ge series materials,

(Sr₁₋ₓDₓ)₂(Nb₁₋ₓDₓ)₂O₇ wherein D is any one of the following dopants: La, Y, Yb, Ta, Ti, V, W, U, or Mo [e.g., SN materials herein disclosed], and
(Sr₁₋ₓBaₓ)_{1-y}D_{y}(Nb_{1-y}D_{y})₂O₆, wherein 0≦x≦1 and 0≦y≦1 wherein D is any one of the following dopants: La, Y, Yb, Al, Ti, V, W, U, or Mo and optionally with minor dopants such as Ca, Fe, Na, and K [e.g., SBN materials herein disclosed].

In an example embodiment, the thermoelectric power generator and storage module includes a p-type thermoelectric element comprising at least NaₓCo₂O₄ or LN and an n-type thermoelectric element comprising at least one compound having a composition represented by the formula (Sr₁₋ₓBaₓ)_{1-y}D_{y}(Nb_{1-y}D_{y})₂O_{z} and (Sr₁₋ₓDₓ)₂(Nb₁₋ₓDₓ)₂O_{z}, wherein 0≦x≦1 and 0≦y≦1; and 5≦z≦7. The thermoelectric power generator and storage module has a figure of merit of greater than 1 and preferably greater than 2.

In an example embodiment, the thermoelectric power generator and storage module includes a plurality of n-type thermoelectric elements coupled to a plurality of p-type thermoelectric elements.

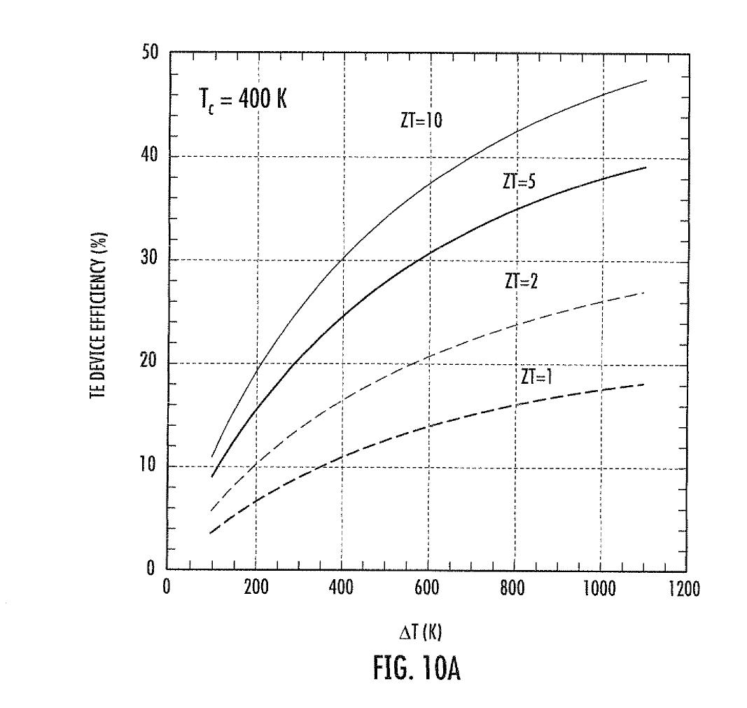

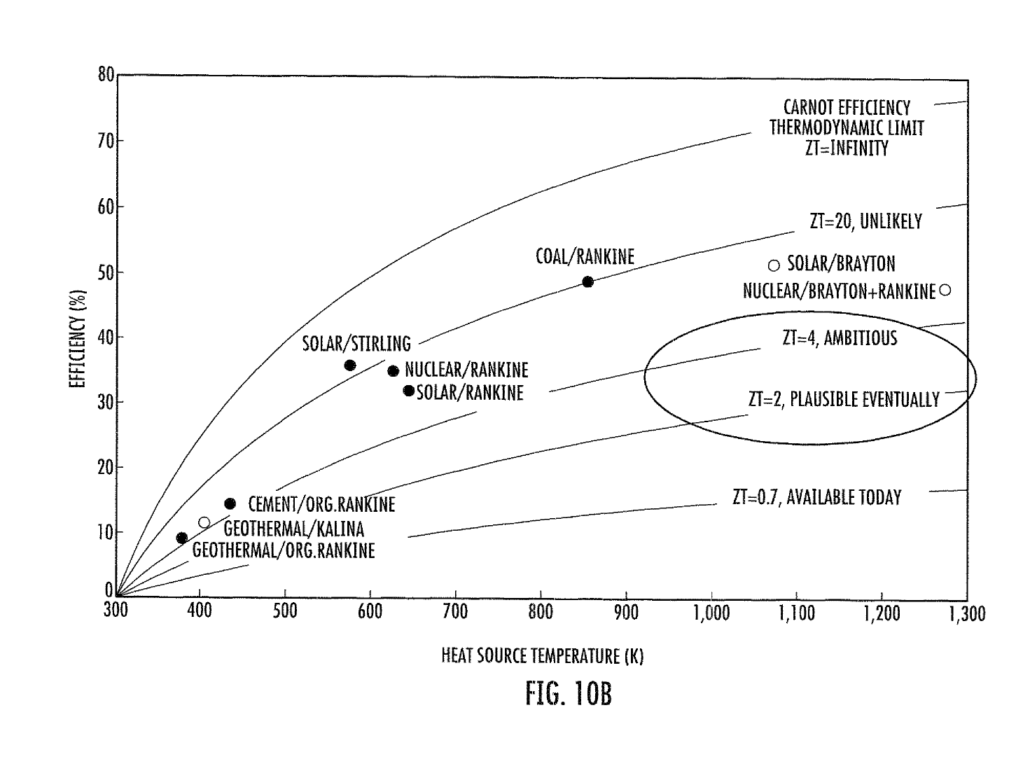

FIGS. 10A through 10B illustrate the thermoelectric efficiency of exemplary thermoelectric devices in terms of the figure of merit (ZT) as a function of temperature according to one embodiment. Thermal efficiency increases as temperature increases. A thermodynamic threshold of maximum energy conversion is reached at Carnot efficiency. Current bulk thermoelectric materials and devices have relatively low figures of merit (ZT) on the order of 1 or less. The p-type and n-type thermoelectric materials and devices herein disclosed have a figure of merit of greater than 0.65 and preferably greater than 2.

Thermoelectric harvesting can be utilized in incinerator and exhaust applications, such as in a factory, power station, household furnace, automobile or any other industrial heat producing process. These devices also can be used to power small devices or sensors requiring low power from low temperature gradients such as body heat. Other thermoelectric applications include the use of thermoelectric materials and devices herein disclosed in heat pumps (thermoelectric cooler), solar thermoelectric converters, thermoelectric sensors, thermal imaging and many other applications that would benefit from the production of electricity from heat.

Example embodiments have been described hereinabove regarding improved p-type and n-type oxide thermoelectric systems, methods and materials. Various modifications to and departures from the disclosed example embodiments will occur to those having ordinary skill in the art. The subject matter that is intended to be within the spirit of this disclosure is set forth in the following claims.

1. An n-type thermoelectric material having a composition represented by the formula
(Sr₁₋ₓBaₓ)_{1-y}D_{y}(Nb_{1-y}D_{y})₂O_{z}, wherein 0≦x≦1.0; y≦1; 5≦z≦7, and having a figure of merit (ZT) greater than 0.5.

2. An n-type thermoelectric material having a composition represented by the formula
(Sr₁₋ₓDₓ)₂(Nb₁₋ₓDₓ)₂O_{z}, wherein 0≦x≦1.0; 5≦z≦7.

3. A p-type thermoelectric material having a composition represented by the formula Li₁₋ₓNbO₂, wherein 0≦x≦0.5, and having a figure of merit (ZT) greater than 0.5.

4. The n-type thermoelectric material as recited in claim 1, wherein the thermoelectric material is a polycrystalline material, a single crystalline material or a textured oriented polycrystalline material.

5. The n-type thermoelectric material as recited in claim 1, having a Seebeck coefficient of greater than or equal to −100 uV/K at 550 K.

6. The n-type thermoelectric material as recited in claim 1, further comprising a reduced phase.

7. A thermoelectric power generator and storage module comprising:
at least one n-type thermoelectric element thermally and electrically coupled to at least one p-type thermoelectric element, wherein the figure of merit (ZT) of the thermoelectric power generator and storage module is greater than 1.

8. The thermoelectric power generator and storage module as recited in claim 7, further comprising at least one conductive element thermally and electrically coupling the n-type thermoelectric element and the p-type thermoelectric element.

9. The thermoelectric power generator and storage module as recited in claim 7, wherein the p-type thermoelectric element comprises at least one compound selected from the group consisting of: Yb₁₄MnSb₁₁, NaₓCo₂O₄, Na_{1.5}Co_{1.8}Ag_{0.2}O₄, LaCoO₃, La_{0.98}Sr_{0.02}CoO₃, Li₁₋ₓNbO₂ (LN), and Si—Ge series materials.

10. The thermoelectric power generator and storage module as recited in claim 7, wherein the n-type thermoelectric element comprises at least one compound selected from the group consisting of: Bi₂Te₃; CaMn₁₋ₓRuₓO₃ wherein 0≦x≦1; Ca₁₋ₓSmₓMnO₃ wherein 0≦x≦1; Sr_{0.98}La_{0.02}TiO₃; Sr_{0.9}Dy_{0.1}TiO₃, Zn_{0.98}Al_{0.02}O, SrTi_{0.8}Nb_{0.2}O₃; Si—Ge series materials; (Sr₁₋ₓDₓ)₂(Nb₁₋ₓDₓ)₂O₇₋ₓ, wherein D is any one of the following dopants: La, Y, Yb, Ti, Ta, V, W, U, or Mo; and (Sr₁₋ₓBaₓ)_{1-y}D_{y}(Nb_{1-y}D_{y})₂O_{6-z} wherein x≦1 and y≦1 and wherein D is any one of the following dopants: La, Y, Yb, Al, Ti, V, W, U, or Mo.

11. The thermoelectric power generator and storage module as recited in claim 7, wherein the n-type thermoelectric element comprises at least one compound represented by the formula (Sr₁₋ₓBaₓ)_{1-y}D_{y}(Nb_{1-y}D_{y})₂O_{z} and (Sr₁₋ₓDₓ)₂(Nb₁₋ₓDₓ)₂O_{z} wherein 0≦x≦1, 0≦y≦1; 5≦z≦7 and wherein D is any one of the following dopants: La, Y, Yb, Al, Ti, V, W, U, or Mo.

12. The thermoelectric power generator and storage module as recited in claim 11, wherein the compound represented by the formula (Sr₁₋ₓBaₓ)_{1-y}D_{y}(Nb_{1-y}D_{y})₂O_{z} and (Sr₁₋ₓDₓ)₂(Nb₁₋ₓDₓ)₂O_{z} is a single crystalline material, a polycrystalline material, or a textured polycrystalline material.

13. The thermoelectric power generator and storage module as recited in claim 12, wherein the p-type thermoelectric element comprises at least one of NaₓCo₂O₄ and Li₁₋ₓNbO₂.

14. A method for manufacturing a thermoelectric power generator and storage module comprising:
providing a plurality of n-type thermoelectric elements and a plurality of p-type thermoelectric elements;
thermally and electrically coupling each n-type thermoelectric element to a p-type thermoelectric element in layered stacked monoliths to form interconnected n-p regions.

15. The method as recited in claim 14, wherein the p-type thermoelectric element comprises at least one compound selected from the group consisting of: Yb₁₄MnSb₁₁, NaₓCo₂O₄, Na_{1.5}Co_{1.8}Ag_{0.2}O₄, LaCoO₃, La_{0.98}Sr_{0.02}CoO₃, Si—Ge series materials, and Li₁₋ₓNbO₂ (LN).

16. The method as recited in claim 14, wherein the n-type thermoelectric element comprises at least one compound selected from the group consisting of: Bi₂Te₃; CaMn₁₋ₓRuₓO₃ wherein 0≦x≦1; Ca₁₋ₓSmₓMnO₃ wherein 0≦x≦1; Sr_{0.98}La_{0.02}TiO₃; Sr_{0.9}Dy_{0.1}TiO₃, Zn_{0.98}Al_{0.02}O, SrTi_{0.8}Nb_{0.2}O₃; Si—Ge series materials; (Sr₁₋ₓDₓ)₂(Nb₁₋ₓDₓ)₂O_{7-z}, wherein D is any one of the following dopants: La, Y, Yb, Ti, Ta, V, W, U, or Mo; and (Sr₁₋ₓBaₓ)_{1-y}D_{y}(Nb_{1-y}D_{y})₂O_{6-z} wherein x≦1 and y≦1 and wherein D is any one of the following dopants: La, Y, Yb, Al, Ti, V, W, U, or Mo.
